(19) United States
(12) Patent Application Publication
(10) Pub. No.: US 2019/0307007 A1
(43) Pub. Date: Oct. 3, 2019

(54) COVER PLATE FOR FLEXIBLE DISPLAY DEVICE AND FLEXIBLE DISPLAY DEVICE USING THE SAME

(71) Applicant: Microcosm Technology Co., LTD, Tainan City (TW)

(72) Inventors: Tang-Chieh Huang, Tainan City (TW); Bo-Hung Lai, Tainan City (TW)

(73) Assignee: Microcosm Technology Co., Ltd.

(21) Appl. No.: 16/175,560

(22) Filed: Oct. 30, 2018

(30) Foreign Application Priority Data
Mar. 31, 2018 (TW) 107111497

(51) Int. Cl. H05K 5/03; G03F 7/00; G03F 7/16; H05K 5/00

(52) U.S. Cl. CPC H05K 5/03; G03F 7/0007; H05K 5/0017; G03F 7/168; G03F 7/162

(57) ABSTRACT

The present invention pertains to a cover plate for a flexible display device. The cover plate comprises a plastic substrate, a flexible layer having a pattern with a height of 5-15 μm on a surface of the plastic substrate, and a hard coating positioned on the surface of the plastic substrate and covering the flexible layer having a pattern. The thickness of the hard coating is 15-30 μm, which is greater than the height of the pattern. The cover plate of the present invention has an excellent flexural property and is suitable for a flexible display device.

### BACKGROUND OF THE INVENTION

### Field of the Invention

The present invention relates to a cover plate for a flexible display device and, more particularly, to a cover plate for a flexible display device with excellent flexural property.

### Description of the Prior Art

In recent years, the development of displays has gradually progressed from thinning to flexible displays that can be bent and deformed. In this development, the cover plate used in the flexible display is no longer a traditional glass substrate, but a flexible substrate made of flexible materials, such as plastics. However, the flexible display easily causes wear and scratches on the cover plate during deformation, thereby causing the display area to be fogged or damaged. In order to solve the problem of the cover plate of such a flexible display, a layer of acrylic or epoxy-based organic hardened film is generally applied to the surface of the plastic material to increase the hardness of the material, but the organic hardened film is not flexible and has surface cracking problems in both bending and impact resistance tests.

### SUMMARY OF THE INVENTION

In view of this, an object of the present invention is to develop a novel cover plate that has excellent flexural properties.

To achieve the above object, the present invention provides a cover plate for a flexible display device. The cover plate comprises a plastic substrate; a flexible layer having a pattern with a height of 5-15 μm on a surface of the plastic substrate; and a hard coating positioned on the surface of the plastic substrate and covering the flexible layer having a pattern. The thickness of the hard coating is 15-30 μm, which is greater than the height of the pattern.

Preferably, the total transmittance of the plastic substrate is 80%.

Preferably, the plastic substrate is selected from colorless polyimide, colorless polyethylene terephthalate (PET), colorless polyethylene naphthalate (PEN), or colorless cyclo-olefin polymer.

Preferably, the thickness of the plastic substrate is 50-200 μm.

Preferably, the flexible layer having a pattern is formed from a composition comprising a monomer having an unsaturated bond and an initiator, and the weight ratio of the monomer having an unsaturated bond to the initiator ranges from 7.5:1 to 120:1.

Preferably, the monomer having an unsaturated bond is selected from glyceryl acrylate, dipentaerythritol hexaacrylate, ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol triacrylate, dipentaerythritol acrylate, pentaerythritol hexaacrylate, Bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, hydroxyethyl methacrylate, isooctyl acrylate, hydroxyethyl acrylate, methyl methacrylate, methacrylic acid, or acrylic acid.

Preferably, the initiator is a photoinitiator or a thermal initiator.

Preferably, the flexible layer having a pattern is built from a plurality of flexible columns or a plurality of flexible strips, and the flexible columns are selected from cylinders, diamond-shaped columns, square columns, or hexagonal columns, More preferably, the flexible strips crisscross to form a plurality of grid structures.

Preferably, the hard coating is partially in contact with the plastic substrate to form a contact surface, the remaining portion of the hard coating is in contact with the flexible layer having a pattern, and the hard coating has a flat surface that is opposite to the contact surface.

Preferably, the hard coating is formed from a composition comprising a monomer having an unsaturated bond; an initiator; and unmodified or modified inorganic nanoparticles. More preferably, the monomer having an unsaturated bond is selected from glyceryl acrylate, dipentaerythritol hexaacrylate, ethylene glycol diacrylate, triethylene glycol diacrylate, 1,4-butanediol diacrylate, 1,6-hexanediol diacrylate, neopentyl glycol diacrylate, pentaerythritol triacrylate, pentaerythritol diacrylate, dipentaerythritol triacrylate, dipentaerythritol acrylate, pentaerythritol hexaacrylate, Bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, hydroxyethyl methacrylate, isooctyl acrylate, hydroxyethyl acrylate, methyl methacrylate, methacrylic acid, or acrylic acid.

Preferably, the ratio of the total weight of the monomer having an unsaturated bond and the initiator to the weight of the unmodified or modified inorganic nanoparticles ranges from 0.66:1 to 2.3:1.

Preferably, the modified inorganic nanoparticles are obtained by reacting the unmodified inorganic nanoparticles with a modifying agent.

Preferably, the area ratio of the hard coating to the flexible layer having a pattern ranges from 0.1 to 50.

The present invention also provides a flexible display device, which comprises a flexible display; and the mentioned cover plate arranged on the flexible display.

Because the cover plate of the present invention includes the flexible layer having a pattern, and the flexible layer can absorb the stress generated by the hard coating, the cover plate of the present invention can prevent cracking or deformation of the material in the bending area. At the same time, the hard coating can give the cover plate a high surface hardness.

### BRIEF DESCRIPTION OF THE DRAWINGS

FIG. 1 is a schematic view showing a cover plate for a flexible display device of the present invention.

FIG. 2A is a schematic diagram illustrating that the flexible layer having a pattern of the present invention is constructed from a plurality of flexible strips.

FIG. 2B is a schematic diagram illustrating that the flexible layer having a pattern of the present invention is constructed from a plurality of flexible strips, and the flexible strips crisscross to form a plurality of grid structures.

FIG. 2C is a schematic diagram illustrating that the flexible layer having a pattern of the present invention is constructed from a plurality of flexible hexagonal columns.

FIG. 3 is a schematic diagram illustrating the manufacturing process of the cover plate for the flexible display device of the present invention.

### DETAILED DESCRIPTION OF THE EMBODIMENTS

The cover plate for the flexible display of the present invention has an alternating soft and hard structure and has a hard coating protection. When being bent, the main stress is concentrated on the flexible layer having a pattern, and the flexible layer further has the hard coating's protection, so that the structure can avoid the generation of cracks or scratches during bending deformation or friction in order to prevent the optical properties from being affected.

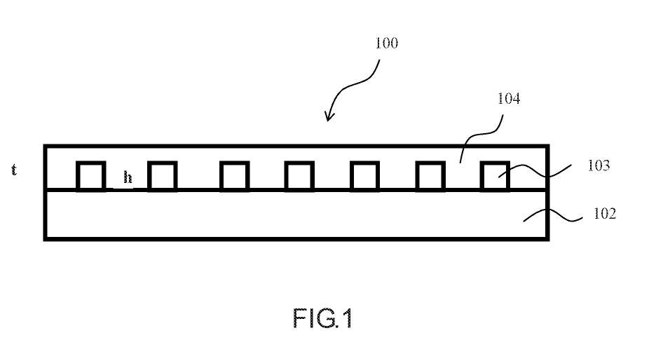

Please refer to FIG. 1, which schematically illustrates the cover plate for a flexible display device of the present invention. As shown in FIG. 1, the cover plate (100) for a flexible display device of the present invention comprises: the plastic substrate (102); the flexible layer (103) on a surface of the plastic substrate, having a thickness of 5-15 μm and patterned by a pattern with a height of 5-15 μm; and the hard coating (104) positioned on the surface of the plastic substrate and covering the flexible layer having a pattern. The thickness (t) of the hard coating is 15-30 μm, which is greater than the height of the pattern. As shown in FIG. 1, the pattern height in the present invention refers to the length extending from the contact surface of the flexible layer having a pattern with the plastic substrate to the top of the pattern, which corresponds to the thickness of the flexible layer. The thickness of the hard coating refers to the distance between the contact surface of the hard coating with the plastic substrate to the top of the hard coating.

In the present invention, examples of the plastic substrate include but are not limited to colorless polyimide, colorless polyethylene terephthalate (PET), colorless polyethylene naphthalate (PEN), or colorless cyclo-olefin polymer (COP). The thickness of the plastic substrate is preferably 50 to 200 μm. According to the measurement of the transmittance by the UV spectrophotometer, the total transmittance is preferably 80% or more, more preferably 90% or more.

The flexible layer having a pattern of the present invention may be located on either side of the plastic substrate, and the flexible layer having a pattern may be formed by patterning an unpatterned flexible layer using conventional methods. The conventional method for forming a pattern includes the lithography process, screen printing, gravure printing, or inkjet method, but is not limited thereto. In the present invention, an unpatterned or patterned flexible layer may be formed from a composition comprising a monomer having an unsaturated bond and an initiator. The initiator may be a photoinitiator or a thermal initiator, and may be used alone or in combination of two or more. The formulation amounts of the monomer having an unsaturated bond and the initiator are not particularly limited. In general, the weight ratio of the monomer having an unsaturated bond to the initiator may be 7.5:1 to 120:1, and preferably 12.5:1 to 50:1 (i.e. 2% by weight to 8°/h by weight). If the amount of the initiator is above the lower limit, the degree of polymerization is maintained at a certain level, so that the polymer formed by the monomer retains the polymer properties. If the amount of the initiator is less than the upper limit, the polymer formed by the monomer won't have the problem of too high polymerization degree and becoming brittle. If the amount of the monomer having an unsaturated bond is too low, the degree of cross-linking of the polymer is insufficient to be hardened. If the proportion of the monomer having an unsaturated bond is too high, the polymer is brittle.

Examples of the monomer having an unsaturated bond include but are not limited to glyceryl acrylate, dipentaerythritol hexaacrylate, ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol triacrylate, dipentaerythritol acrylate, pentaerythritol hexaacrylate, Bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, hydroxyethyl methacrylate, isooctyl acrylate, hydroxyethyl acrylate, methyl methacrylate, methacrylic acid, or acrylic acid. The monomers having an unsaturated bond may be used alone or in combination of two or more, depending on the needs.

Photoinitiators suitable for use in the present invention include, but are not limited to, acetophenones, such as 2-methyl-1-(4-(methylthio)phenyl-2-morpholinylpropyl ketones, 1-hydroxycyclohexyl phenyl ketone, diethoxyacetophenone, 2-hydroxy-2-methyl-1-phenylpropane-1-one, 2-benzyl-2-(dimethylamino)-1-[4-(morpholinyl)phenyl]-1-butanone, other suitable acetophenones; benzoins, such as benzoin, benzoin methyl ether, benzyl dimethyl ketal, other suitable benzoins; diphenyl ketones, such as benzophenone, 4-phenyl benzophenone, hydroxyl benzophenone, or other suitable benzophenones; thioxanthenes, such as isopropyl thioxanthene, 2-chlorothioxanthone, or other suitable thioxanthones; and anthraquinones, such as 2-ethylanthraquinone, or other suitable anthraquinones. The above-mentioned photoinitiators may be used alone or in combination of two or more, depending on the needs of the users. For example, in order to obtain faster photospeed, isopropyl thioxanthone and 2-benzyl-2-(dimethylamino)-1-[4-(morpholinyl)phenyl]-1-butanone may be mixed to serve as the photo initiator.

Thermal initiators suitable for use in the present invention include, but are not limited to, azos, such as 2,2′-azobis(2,4-dimethyl valeronitrile), dimethyl 2,2′-azobis (2-methylpropionate), 2,2′-azobisiso butyronitrile (AlBN), 2,2-azobis(2-methylisobutyronitrile), 1,1′-azobis(cyclohexane-1-carbonitrile), 2,2′-azobis[N-(2-propenyl)-2-methyl propionamide], 1-[(cyano-1-methylethyl)azo]formamide, 2,2′-azobis(N-butyl-2-methylpropionamide), 2,2′-azobis (N-cyclohexyl-2-methylpropionamide), or other suitable azo initiators; peroxides, such as benzoyl peroxide, 1,1-bis(tert-butylperoxy)cyclohexane, 2,5-bis(tert-butylperoxy)-2,5-dimethylcyclohexane, 2,5-bis(tert-butylperoxy)-2,5-dimethyl-3-cyclohexyne, bis(1-(tert-butylpeorxy)-1-methyethyl) benzene, tert-butyl hydroperoxide, tert-butyl peroxide, tert-butyl peroxybenzoate, cumene hydroperoxide, cyclohexanone peroxide, dicumyl peroxide, lauroyl peroxide, or other suitable peroxides. The thermal initiators described above can be used alone or in combination of two or more, depending on the needs.

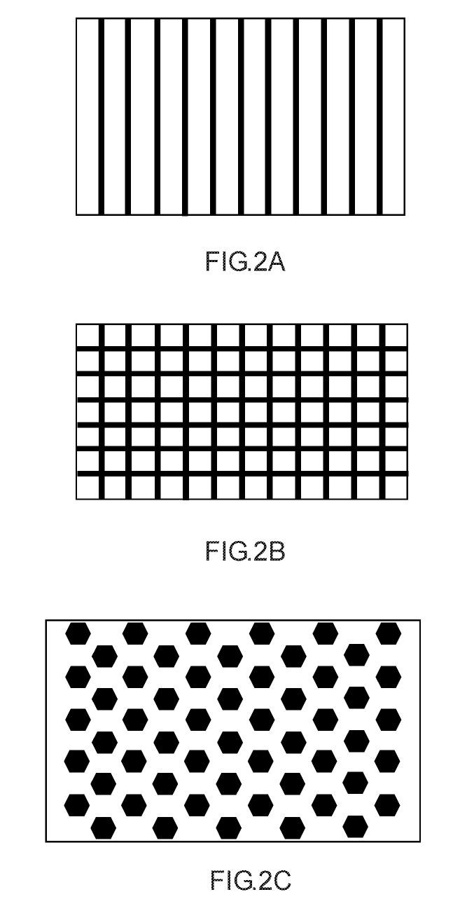

Please refer to FIG. 2, which schematically illustrates the pattern shape of the flexible layer having a pattern of the present invention. As shown in FIGS. 2A through 2B, the flexible layer having a pattern of the present invention may be constructed from a plurality of flexible strips. As shown in FIG. 2B, the flexible strips can crisscross to form a plurality of grid structures. As shown in FIG. 20, the flexible layer having a pattern of the present invention can be constructed from a plurality of flexible columns, which are hexagonal columns. However, actually, the shape of the flexible columns in the present invention may be the same or different. The flexible columns may be cylinders, diamond-shaped columns, square columns, or hexagonal columns. In addition, the flexible columns or flexible strips may be regularly or irregularly arranged, depending on the needs of the user. However, it should be noted that the pattern shape of the flexible layer having a pattern of the present invention should not be limited to or be limited by the aforementioned shapes.

The heights of the respective flexible columns may be the same or different; and the heights of the respective flexible strips may be the same or different. The heights of the flexible columns and strips are all between 5 and 15 μm. The thickness of the hard coating is greater than the heights of the respective flexible columns and strips.

The hard coating referred to in the present invention refers to a thin film coating obtained by thermal curing or light curing of a coating. The hard coating of the present invention is preferably formed from a composition comprising a monomer having an unsaturated bond, an initiator, and unmodified or modified inorganic nanoparticles. The monomer having an unsaturated bond and the initiator are the same as defined above. The monomer having an unsaturated bond used in the hard coating may be the same as or different from the monomer having an unsaturated bond used in the flexible layer; and the initiator used in the hard coating may be the same as or different from the initiator used in the flexible layer. In general, the ratio of the total weight of the monomer having an unsaturated bond and the initiator to the weight of the unmodified or modified inorganic nanoparticles ranges from 0.66:1 to 2.3:1. If the amount of the unmodified or modified inorganic nanoparticles is too high, the hard coating is easy to be fogged and brittle, and if it is too low, the physical properties of the hard coating are low, for example, the hardness is insufficient.

The mixing method of the mixture of the unmodified or modified inorganic nanoparticles, the monomer having the unsaturated bond, and the initiator is not particularly limited, and generally can be performed by ball milling, screwing, planetary mixing, or stirring to make the mixture mix evenly.

The modified inorganic nanoparticles can be obtained by reacting unmodified inorganic nanoparticles with a modifying agent. In the reaction components, the content of the inorganic nanoparticles is preferably 90 to 98% by weight, and the content of the modifying agent is preferably 2 to 10% by weight. The inorganic nanoparticles suitable for use in the present invention include, but are not limited to, titanium dioxide, silica, zirconia, zinc oxide, alumina, and other inorganic metal oxide nanoparticles. The modifying agent suitable for use in the present invention may be a silane coupling agent, which is an organic silicon compound comprising chlorosilane, alkoxysilane, or silazane. The functional group contained in the silane coupling agent may include vinyl, methacryloyloxy, acryloyloxy, amino, urea, chloropropyl, mercapto, polysulfur, or isocyanate, but is not limited thereto. Examples of the silane coupling agent include, but are not limited to, vinyltrichlorosilane, vinyltrimethoxysilane, vinyltriethoxysilane, 3-methacryloyloxypropyl-methyldimethoxysilane, 3-methacryloyloxypropyl-trimethoxysilane, 3-methacryloyloxypropyl-methyldiethoxysilane, 3-methacryloyloxypropyl-triethoxysilane, 3-acryloyloxypropyl-trimethoxysilane, N-2-aminoethyl-3-aminopropylmethyldiethoxysilane, N-2-aminoethyl-3-aminopropyltrimethoxysilane, N-2-aminoethyl-3-aminopropyltriethoxysilane, 3-aminopropyltrimethoxysilane, 3-aminopropyltriethoxysilane, N-phenyl-3-aminopropyltrimethoxysilane, 3-chloropropyltriethoxysilane, 3-mercaptopropyltrimethoxysilane, bis(triethoxymethylsilanepropyl)tetrasulfide, 3-isocyanatepropyltriethoxysilane.

In a preferred embodiment; the hard coating is partially in contact with the plastic substrate to form a contact surface, the remaining portion of the hard coating contacts the flexible layer having a pattern, and the hard coating has a flat surface. The flat surface is opposite to the contact surface.

In the present invention, the area of the hard coating refers to its contact area with the plastic substrate, and the area of the flexible layer having a pattern refers to the contact area between the flexible layer having a pattern and the plastic substrate. The area ratio of the hard coating and the flexible layer having a pattern is preferably 0.1-50.

In the present invention, the flexible layer having a pattern preferably has a pencil hardness of 5B to H, that is, the pencil hardness of the cover plate without the hard coating is preferably 5B to H. After the hard coating is applied, the pencil hardness of the cover plate of the present invention is preferably 7H to 9H.

The present invention also provides a flexible display device, which comprises: a flexible display; and the above-described cover plate disposed on the flexible display.

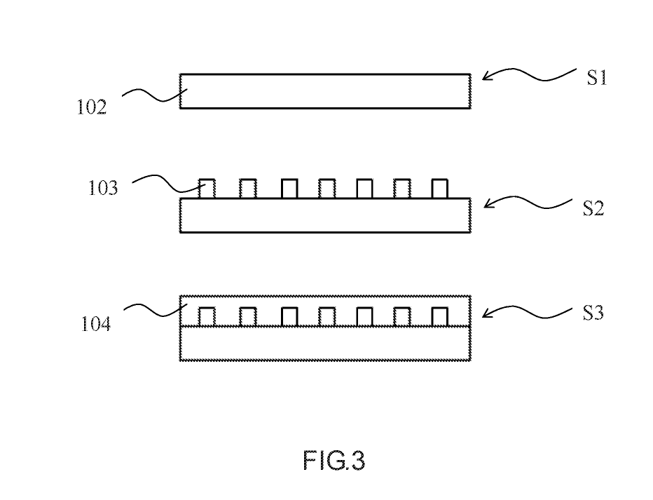

Please refer to FIG. 3, which schematically illustrates the manufacturing process of the cover plate for the flexible display device of the present invention. The manufacturing method includes; providing a plastic substrate (S1); forming a flexible layer having a pattern with a height of 5 to 15 μm on a surface of the plastic substrate, (S2); and forming a hard coating on the surface of the plastic substrate, the hard coating covering the flexible layer having a pattern and having a thickness of 15-30 μm, which is greater than the height of the pattern (S3). A specific embodiment of the second step (S2) comprises: applying a composition comprising a monomer having an unsaturated bond and a initiator to the plastic substrate to form a flexible layer; patterning the flexible layer by using lithography process, screen printing, gravure printing, or ink jet method to obtain a flexible layer having a pattern with a height of 5-15 μm; and curing the flexible layer having a pattern with ultraviolet irradiation or heating. A specific embodiment of the third step (S3) comprises: applying a composition comprising a monomer containing an unsaturated bond, an initiator, and an unmodified or modified inorganic nanoparticles to the surface of the plastic substrate to obtain a coating that covers the flexible layer having a pattern; curing the coating with ultraviolet irradiation or heating to obtain a hard coating, which covers the flexible layer having a pattern and has a thickness greater than the height of the pattern, i.e. 15 to 30 μm. The coating method may be slit coating, spin coating, or screen printing.

The curing using ultraviolet light is performed by irradiating the composition with ultraviolet light having a wavelength of 312 to 365 nm and an energy of 500 to 10,000 mJ/cm² to make the components in the composition cross-link and then cure. The curing using heating is performed by baking the composition at 150 to 200° C. to make the components in the composition cross-link and then cure.

Formulating the Composition for Preparing the Flexible Layer:

28.6 parts by weight of dipentaerythritol hexaacrylate, 1 part by weight of 2-hydroxy-2-methyl-1-phenyl-1-propan-1-one, and 0.6 parts by weight of polyester-modified polydimethylsiloxane serving as a leveling agent were mixed, and appropriate amount of solvents were added according to the solid content to obtain the compositions required for the subsequent examples and comparative examples. The following examples and comparative examples each has a solid content of 50%.

Formulating the Composition for Preparing the Hard Coating:

Both the composition for preparing the flexible layer and the composition for preparing the hard coating can be formed into a coating with high hardness through heat curing or photo curing. The modified inorganic nanoparticles in the hard coating were obtained by the following method: 1 part by weight of a solution of silica nanoparticles and 0.01 parts by weight of 3-methylacryloyloxypropyl-trimethoxysilane were mixed and heated under nitrogen at 50° C. for 4 hours for modification synthesis. After the reaction was completed and down to room temperature, 1 part by weight of the modified nanoparticle solution was added into 0.133 parts by weight of pentaerythritol hexaacrylate. After stirring for 30 minutes, the solution was subjected to phase inversion according to the desired solvent. Finally, a solution of 1.5 parts by weight of the modified inorganic nanoparticles and a monomer having an unsaturated bond is mixed with 0.03 parts by weight of 2-methyl-1-(4-(methylthiol)phenyl-2-morpholinyl propyl ketone and 0.01 parts by weight of leveling agent. Appropriate amount of solvents was added according to the desired solid content to obtain the compositions required for the subsequent examples and comparative examples. The following examples and comparative examples each has a solid content of 50%. The solvent ratio was adjusted according to the set solid content.

### Example 1 (PI+SC−5+HC−15)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 290 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 15 μm thickness. At this time, the area ratio of the hard coating to the flexible layer having a pattern was 4.

### Example 2 (PI+SC−5+HC−30)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 150 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 30 μm thickness. At this time, the area ratio of the hard coating to the flexible layer having a pattern was 4.

### Example 3 (PI+SC−15+HC−30)

The composition for preparing the flexible layer was spin-coated at 800 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 15 μm. Next, the composition for preparing the hard coating was spin-coated at 150 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 30 μm thickness. At this time, the area ratio of the hard coating to the flexible layer having a pattern was 4.

### Example 4 (PI+SC−5+HC−20)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 20 μm thickness. At this time, the area ratio of the hard coating to the flexible layer having a pattern was 0.1.

### Example 5 (PI+SC−5+HC−20)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 20 μm thickness. At this time, the area ratio of the hard coating to the flexible layer having a pattern was 30.

### Example 6 (PI+SC−5+HC−20)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution, Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 20 μm thickness. At this time, the area ratio of the hard coating to the flexible layer having a pattern was 50.

### Example 7 (PET+SC−5+HC−20)

The composition for preparing the flexible layer was spin-coated at 2400 rpm on the surface of the polyethylene terephthalate (PET) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and then hard-baked at 180° C. for 30 minutes to produce a hard coating with 20 μm thickness. At this time; the area ratio of the hard coating to the flexible layer having a pattern was 10.

### Comparative Example 1 (PI+HC−20)

The composition for preparing the hard coating was spin-coated at 240 rpm on the surface of the colorless polyimide (CPI) substrate for 10 seconds, soft baked at 90° C. for 2 minutes, exposed at 100 mJ/cm², and finally hard-baked at 180° C. for 30 minutes to produce a hard coating with 20 μm thickness. The cover plate of Comparative Example 1 didn't have the flexible layer having a pattern, and the area ratio of the hard coating to the flexible layer having a pattern was co.

### Comparative Example 2 (PI+SC−5+HC−10)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 500 rpm on the surface of the colorless polyimide substrate for 10 seconds to cover the flexible layer having a pattern, soft baked at 90° C. for 2 minutes, exposed at 100 mJ/cm², and finally hard-baked at 180° C. for 30 minutes to produce a hard coating with 10 μm thickness. At this time, the area ratio of the hard coating to the flexible layer having a pattern was 4.

### Comparative Example 3 (PI+SC−15+HC−35)

The composition for preparing the flexible layer was spin-coated at 800 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution, Finally, hard baking was performed at 200° C. for 30 minutes to produce the flexible layer having a pattern and a thickness of 15 μm, Next, the composition for preparing the hard coating was spin-coated at 140 rpm on the surface of the colorless polyimide substrate for 10 seconds to cover the flexible layer having a pattern, soft baked at 90° C. for 2 minutes, exposed at 100 mJ/cm², and finally hard-baked at 189° C. for 30 minutes to produce a hard coating with 35 μm thickness. At this time, the area ratio of the hard coating to the flexible layer having a pattern was 4.

### Comparative Example 4 (PI+SC−5+HC−20)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution. Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and finally hard-baked at 180° C. for 30 minutes to produce a hard coating with 20 μm thickness. At this time, the area ratio of the hard coating to the flexible layer having a pattern was 0.05.

### Comparative Example 5 (PI+SC−5+HC−20)

The composition for preparing the flexible layer was spin-coated at 2500 rpm on the surface of the colorless polyimide (CPI) substrate for 10 seconds, soft baked at 80° C. for 5 minutes, exposed at 100 mJ/cm², and then developed with a developer having a pH of 11.5 at a rate of 0.1 M/min. The developer was a 0.05% KOH aqueous solution, Finally, hard baking was performed at 200° C. for 30 minutes to produce the flexible layer having a pattern and a thickness of 5 μm. Next, the composition for preparing the hard coating was spin-coated at 240 rpm on the surface of the colorless polyimide substrate for 10 seconds to cover the flexible layer having a pattern, soft baked at 90° C. for 2 minutes, exposed at 100 mJ/cm², and finally hard-baked at 180° C. for 30 minutes to produce a hard coating with 20 μm thickness. At this time, the area ratio of the hard coating to the flexible layer having a pattern was 60.

Performance Evaluation

Thickness Measurement

The thickness of each plastic substrate was measured with a thickness gauge, and then the height of the flexible layer having a pattern on the plastic substrate was measured with an Alpha Step. Finally, the thickness of each cover plate was measured by the thickness gauge, and the thickness of the hard coating was determined by subtracting the thickness of the plastic substrate from that of the cover plate.

Determination of Pencil Hardness

Using an electronic pencil hardness tester, a 10 mm long line was drawn five times on each of the cover plates with a Mitsubishi test pencil at a speed of 30 mm/min under a load of 750 g, and then the surface scratches were observed versus the pencil hardness.

Determination of Total Light Transmittance (%)

The total light transmittance of the cover plate was measured using Nippon Denshoku NDH 7000.

Abrasion Resistance

The substrate was rubbed with a steel wool having a length of 100 mm at a speed of 50 mm/s under a load of 1000 g 500 times, and then the number of scratches on the substrate was determined with naked eyes and the microscope. Those that have scratches are unqualified; those that have no scratch are passed.

Flexural Property

The cover plate was attached to a YUASA System U-shape Folding tester and folded 10,000 times at R=3 mm. The cover plate was observed first for the presence or absence of a fracture, and then the hard coating was observed with naked eyes and the microscope for the presence or absence of a crack. Any case where the cover plate has a fracture or the hard coating has a crack is marked as unqualified (X), and where the cover plate has no fracture or the hard coating has no crack is marked as qualified (◯).

The test results of the foregoing performance evaluation are recorded in Table 1.

TABLE 1

| | | | The height of | The area ratio | | | | |
|---|---|---|---|---|---|---|---|---|
| | | | the flexible | of the hard | | | | |
| | | Total | layer having | coating to the | | | | |
| | | thickness | a pattern | flexible layer | Pencil | Abrasion | Flexural | |
| No. | Substrate | (μm) | (μm) | having a pattern | Hardness | Resistance | property | Transmittance |
| Example 1 | CPI | 15 | 5 | 4 | 8H | ◯ | ◯ | 90.2% |
| Example 2 | CPI | 30 | 5 | 4 | 9H | ◯ | ◯ | 90.3% |
| Example 3 | CPI | 30 | 15 | 4 | 9H | ◯ | ◯ | 90.5% |
| Example 4 | CPI | 20 | 5 | 0.1 | 9H | ◯ | ◯ | 89.8% |
| Example 5 | CPI | 20 | 5 | 30 | 9H | ◯ | ◯ | 90.5% |
| Example 6 | CPI | 20 | 5 | 50 | 9H | ◯ | ◯ | 90.8% |
| Example 7 | PET | 20 | 5 | 10 | 9H | ◯ | ◯ | 91.3% |
| Comparative | CPI | 20 | 0 | ∞ | 9H | ◯ | X | 90.8 |
| Example 1 | | | | | | | | |
| Comparative | CPI | 10 | 5 | 4 | 6H | X | X | 90.3 |
| Example 2 | | | | | | | | |
| Comparative | CPI | 35 | 15 | 4 | 9H | ◯ | X | 90.3 |
| Example 3 | | | | | | | | |
| Comparative | CPI | 20 | 5 | 0.05 | 8H | ◯ | X | 89.7 |
| Example 4 | | | | | | | | |
| Comparative | CPI | 20 | 5 | 60 | 9H | ◯ | X | 90.8 |
| Example 5 | | | | | | | | |

The result of Comparative Example 1 shows that if the cover plate of the flexible display device doesn't have a flexible layer having a pattern, though the pencil hardness may be as high as 9H, the cover plate may be broken during the bending. The results from Examples 2 to 7 show that when the hardness of the hard coating reaches 20 μm or more, the pencil hardness thereof can reach 9H and pass the bending test. The results from Example 1 and Comparative Example 2 show that when the thickness of the hard coating is less than 15 μm, the pencil hardness thereof is less than 7H, and only 5 μm of the hard coating is provided on the flexible layer having a pattern, resulting in crack formation during folding. The results from Example 3 and Comparative Example 3 show that when the thickness of the hard coating is more than 30 μm, the pencil hardness thereof can all reach 9H, and, however, the cover plate breaks during bending for the thickness of the hard coating is too thick.

The results from Examples 4 and 6 and Comparative Examples 4 and 5 show that when the area ratio of the hard coating to the flexible layer having a pattern is greater than 50 and when the coating is mainly a hard coating, the result is relatively close to that of the situation where the cover plate doesn't have the patterned flexible layer. Therefore, the cover plate may be broken after being bent. When the area ratio of the hard coating to the flexible layer having a pattern is less than 0.05, the hard coating can't fill in the gap effectively for the area of the hard coating is too small. Therefore, the cracks appear in the hard coating during folding.

In summary, the cover plate for the flexible display device of the present invention can solve the problems in the prior art due to its excellent flexural property, scratch resistance and abrasion resistance.

What is claimed is:

1. A cover plate for a flexible display device, comprising:
a plastic substrate;
a flexible layer having a pattern with a height of 5-15 μm on a surface of the plastic substrate; and
a hard coating positioned on the surface of the plastic substrate and covering the flexible layer having a pattern; wherein the hard coating has a thickness of 15-30 μm, which is greater than the height of the pattern.

2. The cover plate of claim 1, wherein the total transmittance of the plastic substrate is 80%.

3. The cover plate of claim 1, wherein the plastic substrate is selected from colorless polyimide, colorless polyethylene terephthalate (PET), colorless polyethylene naphthalate (PEN), or colorless cyclo-olefin polymer.

4. The cover plate of claim 1, wherein the thickness of the plastic substrate is 50-200 μm.

5. The cover plate of claim 1, wherein the flexible layer having a pattern is formed from a composition comprising a monomer having an unsaturated bond and an initiator, and the weight ratio of the monomer having an unsaturated bond to the initiator ranges from 7.5:1 to 120:1.

6. The cover plate of claim 5, wherein the monomer having an unsaturated bond is selected from glyceryl acrylate, dipentaerythritol hexaacrylate, ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol triacrylate, dipentaerythritol acrylate, pentaerythritol hexaacrylate, Bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, hydroxyethyl methacrylate, isooctyl acrylate, hydroxyethyl acrylate, methyl methacrylate, methacrylic acid, or acrylic acid.

7. The cover plate of claim 5, wherein the initiator is a photoinitiator or a thermal initiator.

8. The cover plate of claim 1, wherein the flexible layer having a pattern is built from a plurality of flexible columns or a plurality of flexible strips, and the flexible columns are selected from cylinders, diamond-shaped columns, square columns, or hexagonal columns.

9. The cover plate of claim 8, wherein the flexible strips crisscross to form a plurality of grid structures.

10. The cover plate of claim 1, wherein the hard coating is partially in contact with the plastic substrate to form a contact surface, the remaining portion of the hard coating is in contact with the flexible layer having a pattern, and the hard coating has a flat surface that is opposite to the contact surface.

11. The cover plate of claim 1, wherein the hard coating is formed from a composition comprising a monomer having an unsaturated bond; an initiator; and unmodified or modified inorganic nanoparticles.

12. The cover plate of claim 11, wherein the ratio of the total weight of the monomer having an unsaturated bond and the initiator to the weight of the unmodified or modified inorganic nanoparticles ranges from 0.66:1 to 2.3:1.

13. The cover plate of claim 11, wherein the modified inorganic nanoparticles are obtained by reacting the unmodified inorganic nanoparticles with a modifying agent.

14. The cover plate of claim 11, wherein the monomer having an unsaturated bond is selected from glyceryl acrylate, dipentaerythritol hexaacrylate, ethylene glycol diacrylate, triethylene glycol diacrylate, 1,4-butanediol diacrylate, 1,6-hexanediol diacrylate, neopentyl glycol diacrylate, pentaerythritol triacrylate, pentaerythritol diacrylate, dipentaerythritol triacrylate, dipentaerythritol acrylate, pentaerythritol hexaacrylate, Bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, hydroxyethyl methacrylate, isooctyl acrylate, hydroxyethyl acrylate, methyl methacrylate, methacrylic acid, or acrylic acid.

15. The cover plate of claim 1, wherein the area ratio of the hard coating to the flexible layer having a pattern ranges from 0.1 to 50.

16. A flexible display device comprising: a flexible display; and a cover plate of any one of claims 1-15 arranged on the flexible display.
